(19) United States
(12) Patent Application Publication
(10) Pub. No.: US 2014/0332067 A1
(43) Pub. Date: Nov. 13, 2014

(54) Via Fill Material For Solar Applications

(71) Applicants: George E. Graddy, JR., Del Mar, CA (US); Caroline M. McKinley, Oceanside, CA (US); Aziz S. Shaikh, San Diego, CA (US)

(72) Inventors: George E. Graddy, JR., Del Mar, CA (US); Caroline M. McKinley, Oceanside, CA (US); Aziz S. Shaikh, San Diego, CA (US)

(21) Appl. No.: 13/819,862

(22) PCT Filed: Sep. 1, 2011
(86) PCT No.: PCT/US11/50145

§ 371 Date: Mar. 19, 2014

Related U.S. Application Data
(60) Provisional application No. 61/378,959, filed on Sep. 1, 2010.

(51) Int. Cl. H01L 31/0224; H05K 3/42

(52) U.S. Cl. CPC H01L 31/022425; H05K 3/42; H05K 2203/1126
USPC 136/256; 29/852; 252/514

(57) ABSTRACT

The present invention is directed toward a via fill material for use in solar applications that exhibits low series resistance and high shunt resistance. The via fill material according to the invention includes silver powder, a glass frit and a vehicle.

### BACKGROUND OF THE INVENTION

1. Field of Invention

The present invention relates to a via fill material for use in solar applications that exhibits low series resistance and high shunt resistance. This new solar cell structure is a back contact solar cell device. In this device the contacts to the p and n surfaces are made on the backside of the solar cell. Such structures have advantages in terms of reducing shadow losses and hence increasing solar efficiency. This invention particularly deals with a key metallization which connects the front side of the solar cell to the backside through a hole as shown in FIG. 1.

2. Description of Related Art

Solar cells, which are also sometimes referred to in the art as photovoltaic cells, convert solar energy into electricity by means of the photoelectric effect. The most commonly known solar cells comprise large-area P-N junction devices. Such solar cells typically comprise a silicon wafer that has been doped on an N-side with phosphorous and on a P-side with boron. A metal contact grid is formed on the N-side of the silicon wafer (typically on an antireflective coating). A back contact is formed on the P-side of the silicon wafer. When photons hit the solar cell, electrons are freed from the N-side of the silicon wafer. The freed electrons cannot cross the P-N junction and thus flow through the contact grid, which is electrically connected to a collector grid formed on an insulating layer on the back contact. The electrical connection between the contact grid and the collector grid is established by means of an electrically-conductive via fill material, which fills a via through the silicon wafer. The electrons flow from the collector grid through an external circuit (not shown) to the back contact, where they fill free “holes” in the P-side of the silicon wafer. The electron flow through the external circuit provides current (“I”), and the solar cell's electric field causes a voltage (“V”), the product of which is power (“P”).

It is known that the power produced by a solar cell can be dissipated through two parasitic types of resistance, which are referred to as series resistance (“Rₛ”) and shunt resistance (“Rₛₕ”). Series resistance arises from the inherent resistance to current flow of the materials from which the solar cell is manufactured (especially the flow of electrons from the N-side of the silicon wafer to the contact grid) and from resistive contacts. Shunt resistance arises to prevent leakage of current through the P-N junction formed in the solar cell. To maximize the efficiency of a solar cell, series resistance should be made as small as possible whereas shunt resistance should be made as large as possible.

### BRIEF SUMMARY OF THE INVENTION

The formation of an electrically conductive pathway through a via presents a particularly difficult problem in terms of managing parasitic resistance in a solar cell. On one hand, it is desirable for the via fill material to exhibit low inherent resistance in order to minimize series resistance. But because the via fill material contacts the silicon wafer within the via, the via fill material can also form an electrically conductive path (shunt) across the P-N junction, disadvantageously leading to low shunt resistance.

In view of the foregoing, the present invention is directed toward a via fill material for use in solar applications that exhibits low series resistance and high shunt resistance. The via fill material according to the invention comprises silver powder, special oxides, a glass frit and a vehicle. An alternate type of solar cell is the emitter wrap through cell (EWT) wherein a silicon wafer has via holes formed in it, that connect the n-side (a major surface) to the p-side (a major surface). The holes may be formed by chemical etching, mechanical drilling or lasers, for example. The via holes are next lined with an electrically insulating material. The insulated via holes are then filled with a paste including a conductive material, usually a metal such as silver, and a glass frit. The silicon wafer filled with the paste is then fired to sinter the metal and fuse the frit. A conductive pathway is thus formed from the n-side to the p-side of the wafer, through the thickness of the wafer. Lateral electrical conduction is prevented through the silicon wafer owing to the insulating material pre-applied to the via holes. Ways of fabricating emitter wrap through solar cells are taught in U.S. 2011/0192826, which is hereby incorporated by reference.

In particular, referring to FIG. 1, which is a generalized and stylized depiction of an EWT solar cell, a silicon wafer 10 has an n-side and a p-side. A via hole (not shown) is formed in the wafer 10, providing a passage between the n-side and p-side. An insulating layer 50 is applied to the inner surface of the via hole and at least a portion of the surface of the n-side of wafer 10. The via hole is filled with a paste 60 including metal and glass frit. A passivation layer 70 such as SiNₓ or SiO₂ is applied to at least a portion of insulating layer 50 on the n-side of wafer 10. It may cover exposed parts of the paste 60.

Next, the wafer 10 with paste 60 filled in the via hole is fired to sinter the metal and fuse the glass in the paste, forming a plug. Or, instead of firing only the via hole paste 60, a contact may be printed from another paste on both the n-side (80) and p-side (90) of the wafer. Each paste 80 and 90 covers at least a portion of the exposed end of the paste 60. The n-side contact 80 may cover a portion of the passivation layer 70. If the via paste 60 was previously fired, then contacts 80 and 90 can be printed over the fired ends of the plug, and fired separately.

The paste composition developed herein fills the via hole and upon firing forms a solid plug. This solid plug has low resistance and does not react with emitter in the via hole to cause shunting. The emitter is a p-n junction formed by diffusing Phosphorous into silicon wafer. The paste is also solderable and has high adhesion. In some instances this via-fill paste also can be covered with another paste to form a highly solderable contact point.

There are three main features of the invention. The first feature deals with control of sintering during the firing process. This is achieved through careful selection of metal powders with certain particle size, use of glasses with certain melting point and oxides which affect the sintering behavior. The second feature relates to shunting behavior. Excellent shunt performance is achieved by controlling reaction between via-fill paste and the surrounding hole. This is controlled through selection of glass and proportions of oxides. The third feature is related to solderability and adhesion of the fired film. This is achieved by selection of glass having reactivity towards silicon wafer and selection of metal powder which during the sintering process does not squeeze glass to the surface. In addition to the above the paste rheology is controlled to achieve good via filling through selection of organic resin.

The foregoing and other features of the invention are hereinafter more fully described and particularly pointed out in the claims, the following description setting forth in detail certain illustrative embodiments of the invention, these being indicative, however, of but a few of the various ways in which the principles of the present invention may be employed.

### BRIEF DESCRIPTION OF THE DRAWINGS

FIG. 1 is a schematic stylized cross-sectional view of a solar cell.

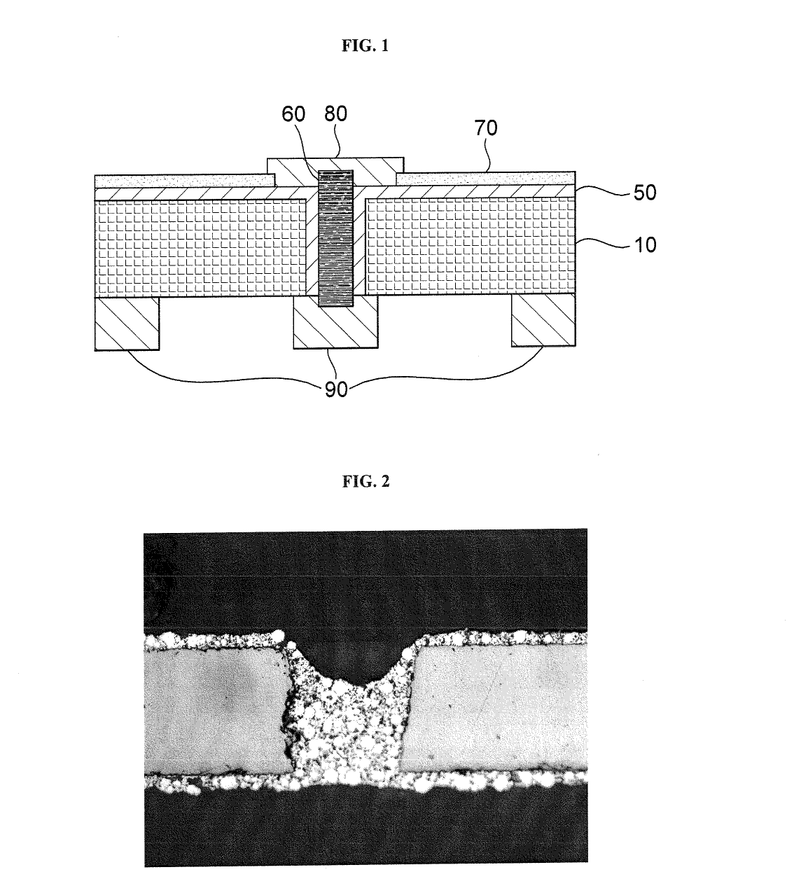

FIGS. 2-4, are photomicrographs showing cross-sectional views of vias formed in the Examples.

### DETAILED DESCRIPTION OF THE INVENTION

The via fill material of the invention includes, before it is fired, silver powder and glass frit. The particular characteristics of the silver powder and glass frit determine the behavior of solar cells using plugs made of the inventive via fill material.

The via fill material according to the invention preferably comprises from about 65% to about 90% by weight of silver powder. More preferably, the via fill material according to the invention comprises from about 74% to about 87% by weight of silver powder. The silver powder should be of ordinary high purity (99+%).

It is believed that packing density is improved when silver powders having two or more different D₅₀ particle sizes be used (i.e., a bi-modal, tri-modal or multi-modal particle size distribution).The silver powder preferably has a D₅₀ average particle size (sometimes shortened to D₅₀ size) within the range of from about 0.25 micron to about 30 microns.

For a first portion of the silver powder the D₅₀ size is 0.5 to 5 microns, preferably 1-4.5 microns, more preferably 1.5-3.5 microns, for example 2-3 microns. For a second portion of the silver powder, the D₅₀ size is 0.5-2.5 microns, preferably 0.75-2.25 microns, more preferably 1-2 microns, for example 1.25-1.75 microns. For a third portion of the silver powder, the D₅₀ size is 0.1-1.5 microns, preferably 0.3-1.3 microns, more preferably 0.5-1.0 microns, for example 0.6-0.9 microns.

An alternate silver powder, which may be termed first, second third or something else in context, has a D₅₀ size is 2-20 microns, preferably 3-15 microns, more preferably 4-10 microns, still more preferably 5-9 microns, for example 6-8 microns.

It is envisioned that various combinations of the first, second, third and alternate silver powders in various proportions may be used in inventive embodiments of the invention.

For example, the paste may comprise 20-50 wt % of the first portion of silver powder, 30-50 wt % of the second portion of silver powder and 0.1-10 wt % of the third portion. Preferably, the paste may comprise 25-45 wt % of the first portion of silver powder, 35-45 wt % of the second portion of silver powder and 2-8 wt % of the third portion of silver powder Alternately, the paste may comprise 30-40 wt % of the first portion of silver powder, 30-40 wt % of the second portion of silver powder and 3-7 wt % of the third portion of silver powder.

In another embodiment of the invention, the paste comprises 40-70 wt % of the alternate portion of silver powder, 5-25 wt % of the second portion of silver powder and 1-20 wt % of the third portion of silver powder. Preferably, the paste comprises 45-65 wt % of the alternate portion of silver powder, 10-20 wt % of the second portion of silver powder and 5-15 wt % of the third portion of silver powder. More preferably, the paste comprises 50-60 wt % of the alternate portion of silver powder, 12-18 wt % of the second portion of silver powder and 6-10 wt % of the third portion of silver powder.

Various silver particle surface areas (SSA, measured by the BET method) have utility in the invention. For example, a surface area of 0.01-1.0 m²/g, or 0.1-0.5 m²/g, or 0.2-0.6 m²/g; or 0.3-0.8 m²/g, for example 0.22 m²/g or 0.84 m²/g.

There are two morphologies of Ag powder are envisioned: flat flake and spherical. The preferred silver is a combination of spherical and flaked powders. Two or three Ag powders with different sizes and shapes were blended to control the shrinkage upon sintering. The Ag particles were coated with fatty acids and their soaps to achieve desired rheology.

The via fill material according to the invention also preferably comprises from about 0.01% to about 10% by weight of one or more glass frits, or 1-10 wt %. The glass frit(s) used in the present invention preferably have a softening point within the range of from about 250° C. to 650° C., preferably about 300° C. to about 600° C. as measured by Labino Softening Point apparatus. The chemical composition of the glass frit(s) is critical to assure no firethrough occurs. For example, lead vanadium phosphate glasses (“Pb—V—P”) and lead-zinc aluminosilicate glasses (Pb—Zn—Al—Si) having the compositions set forth in Table 1 below can be used:

TABLE 1
Glass composition ranges in weight %

| | Pb—V—P | Pb—Zn—Al—Si |
|---|---|---|
| PbO | 20-40 | 45-70 |
| ZnO | — | 10-30 |
| SiO2 | — | 5-25 |
| Al2O3 | — | 1-15 |
| P2O5 | 5-20 | — |
| V2O5 | 45-70 | — |
| Ta2O5 | — | 1-10 |

The glass fit should be milled to a fineness of from about 2 to about 5 microns average particle size (D₅₀). Particle size is measured by light-scattering, for example laser light scattering, with a device such as a Microtrac X-100 Particle Size Analyzer. The glass transition temperatures (Tg) of the preferred glasses are preferably in the range of 250 to 650° C., and most preferably in the range 300 to 550° C.

It is envisioned that glass frits useful for this invention, i.e. to control the reactivity and adhesion to silicon, can be predominately crystallizing type, or a combination of crystallizing and non-crystallizing frits or a combination of non crystallizing frits and reactive crystalline materials that dissolve in the glass during contact formation. The preferred frits are of partly crystallizing types.

It is also envisioned that additives such as copper oxide, manganese oxide, cobalt oxide, vanadium oxide, zinc oxide, iron oxides and their combinations, as well as their reaction products with aluminum oxide such as cobalt aluminates can be used to promote adhesion to silicon.

The via fill material can further optionally comprise one or more inorganic fillers such as, for example, zirconia, bismuth oxide, alumina, titania, zirconium silicates such as zircon, zinc silicates such as willemite, crystalline silica, cordierite, bentonite and/or Hectorite in a total amount up to about 10% by weight. The inorganic fillers should have a D₅₀ average particle size within the range of from about 20 nanometers to about 10 microns, preferably 50 nm to 5 microns, more preferably 100 nm to 1 micron.

The silver powder, glass frit(s) and optional inorganic fillers are preferably mixed together in the aforementioned amounts with from about 5% to about 20% by weight of one or more organic vehicle or carrier compositions. The organic vehicle or carrier compositions preferably comprise one or more resins dissolved in one or more solvent and, optionally, one or more thixotropic agents. In a preferred embodiment, the organic vehicle compositions comprise at least about 80% by weight of one or more organic solvents, up to about 15% by weight of one or more thermoplastic resins, up to about 4% by weight of one or more thixotropic agents and up to about 2% by weight of one or more wetting agents.

Ethyl cellulose is a preferred resin for use in the invention, but resins such as ethyl hydroxyethyl cellulose, wood rosin, mixtures of ethyl cellulose and phenolic resins, polymethacrylates of lower alcohols and the monobutyl ether of ethylene glycol monoacetate can also be used. Solvents having boiling points (at 1 atm) of from about 130° C. to about 350° C. are suitable. Suitable solvents include terpenes such as alpha- or beta-terpineol or higher boiling alcohols such as Dowanol® (diethylene glycol monoethyl ether), or mixtures thereof with other solvents such as butyl Carbitol® (diethylene glycol monobutyl ether); dibutyl Carbitol® (diethylene glycol dibutyl ether), butyl Carbitol® acetate (diethylene glycol monobutyl ether acetate), hexylene glycol, Texanol® (2,2,4-trimethyl-1,3-pentanediol monoisobutyrate), as well as other alcohol esters, kerosene, and dibutyl phthalate. Various combinations of these and other solvents can be formulated to obtain the desired viscosity and volatility requirements for each application. Other dispersants, surfactants and rheology modifiers, which are commonly used in thick film paste formulations, may be included. Commercial examples of such products include those sold under any of the following trademarks: Texanol® (Eastman Chemical Company, Kingsport, Tenn.); Dowanol® and Carbitol® (Dow Chemical Co., Midland, Mich.); Triton® (Union Carbide Division of Dow Chemical Co., Midland, Mich.), Thixatrol® (Elementis Company, Hightstown N.J.), and Diffusol® (Transene Co. Inc., Danvers, Mass.).

Among commonly used organic thixotropic agents is hydrogenated castor oil and derivatives thereof. A thixotrope is not always necessary because the solvent coupled with the shear thinning inherent in any suspension may alone be suitable in this regard. Furthermore, wetting agents may be employed such as fatty acid esters, e.g., N-tallow-1,3-diaminopropane dioleate; N-tallow trimethylene diamine diacetate; N-coco trimethylene diamine, beta diamines; N-oleyl trimethylene diamine; N-tallow trimethylene diamine; N-tallow trimethylene diamine dioleate, and combinations thereof.

The via fill material according to the invention may be conveniently prepared using a three-roll mill. The amount and type of vehicle utilized are determined mainly by the final desired formulation viscosity and fineness of grind of the material. For solar applications, the viscosity is preferably adjusted to be within the range of about 100 to about 500 kcps, preferably about 300 to about 400 kcps, at a shear rate of 9.6 sec⁻¹ as determined on a Brookfield viscometer HBT, spindle 14, measured at 25° C.

The via fill material according to the invention is preferentially adapted for use in filling vias in solar cells to provide electrically conductive pathways from a contact grid formed on the N-side of the silicon wafer to a collector grid formed on an insulating layer on the back contact. The via fill material is applied using a conventional thick film application method, dried and fired. During firing, the via fill material sinters and densifies. Firing can be accomplished at a wafer temperature within the range of from about 550° C. to about 850° C. using conventional firing equipment and an air atmosphere.

Without being bound to a particular theory, applicants believe that at least a portion of the glass frit in the via fill material according to the invention migrates to and/or coats the silicon wafer that defines the via during firing, whereas the silver powder in the via fill material according to the invention sinters and/or fuses to form a metallic plug between the front contact grid and the back side contact point. Thus, electrons can flow through the metallic traces at low series resistance (Rₛ), but the glass coating on the silicon wafer provides adhesion to silicon, most precisely adhesion to the passivation layer on silicon. However the reaction between the Silicon and glass is controlled to prevent shunting by optimum selection of glass Tg and use of different oxides.

The shunting characteristics of via-fill can be measure through Current−Voltage (I−V) response of solar cells. For excellent solar cell performance the Shunt resistance needs to be >1 Kohms. The preferred paste in this invention resulted in shunt resistance >20 Kohms.

The following examples are intended only to illustrate the invention, and should not be construed as imposing limitations upon the claims.

### EXAMPLES

Polycrystalline silicon wafers, 12.5 cm×12.5 cm, thickness 250-300 μm, were coated with a silicon nitride antireflective coating on the N-side of the wafer. The sheet resistivity of these wafers was about 1 Ω-cm. A contact grid was formed on the antireflective coating using Ferro NS33-502 and NS33-503 pastes, commercially available from Ferro Corporation, Vista, Calif., by screen printing.

Vias on the order of 200 microns in diameter were formed through the wafers using laser drilling before diffusion process.

Two glass frits were separately produced using conventional glass making techniques so as to achieve a composition shown in parts by weight in Table 2:

TABLE 2
Glass Compositions in weight %

| | 1 | 2 |
|---|---|---|
| PbO | 28.9 | 56.1 |
| ZnO | — | 19.6 |
| SiO2 | — | 14.4 |
| Al2O3 | — | 6.6 |
| P2O5 | 12.3 | — |
| V2O5 | 58.8 | — |
| Ta2O5 | — | 3.3 |

Each of the glass frits was separately milled to a fineness of 2 to 5 microns D50. Three via fill material compositions according to the invention were prepared by blending the components listed in parts by weight in Table 3 below using a three-roll mill:

TABLE 3
Paste compositions in weight %

| | A | B | C | D | E |
|---|---|---|---|---|---|
| Ag Powder I (6.4 μm) | — | — | — | — | 57.3 |
| Ag Powder II (3.0 μm) | 36.1 | 36.1 | 36.1 | 35.8 | — |
| Ag Powder III (1.5 μm) | 38.8 | 38.8 | 38.8 | 39.7 | 14.2 |
| Ag Powder IV (0.8 μm) | 4.5 | 4.5 | 4.5 | 4.5 | 8.5 |
| Glass Frit 1 | — | — | 4.4 | 3.0 | 3.0 |
| Glass Frit 2 | 4.4 | 4.4 | — | — | |
| Zirconia Powder | 0.79 | 1.55 | 1.55 | 0.5 | |
| Alumina Powder | 0.74 | 1.55 | 1.55 | — | |
| Bentonite | 0.51 | — | — | — | |
| Hectorite | 1.0 | — | — | — | |
| Bi2O3 | — | — | — | 1.5 | 3.0 |
| Vehicle A308-5VA | 2.87 | 4.0 | 4.0 | — | — |
| Vehicle 626 | | | | 6.0 | 6.0 |
| Vehicle 131 | 2.91 | — | — | — | — |
| Vehicle 132 | 4.61 | 4.2 | 4.2 | — | — |
| Vehicle 473 | 1.77 | 2.5 | 2.5 | 7.5 | 7.5 |

Ag powders I-IV correspond to silver powders commercially available from Ferro Corporation, South Plainfield N.J., respectively Silver Flake #125; Silver Powder 11000-04; Silver Powder 7000-07, and Silver Powder 14000-06.

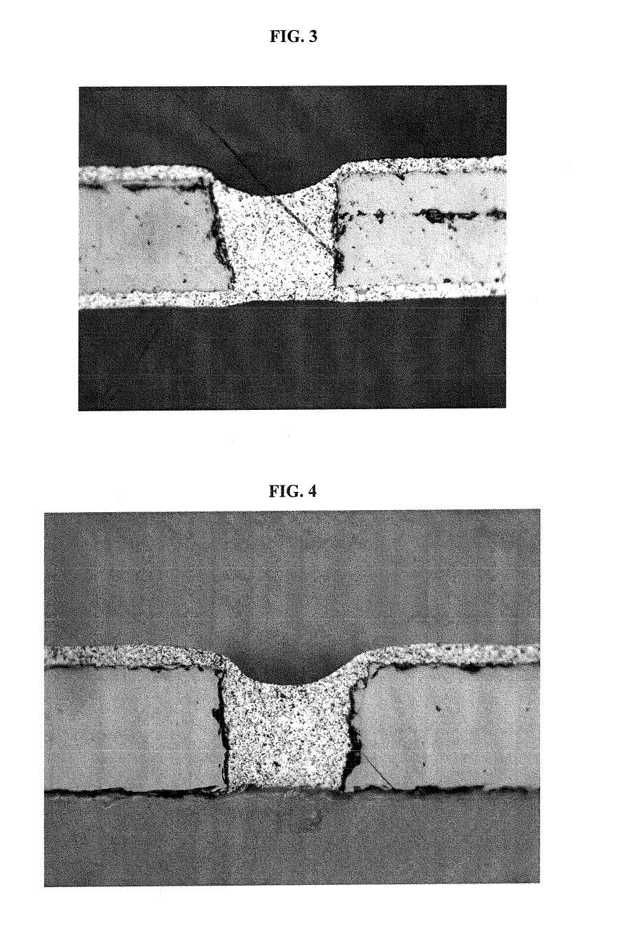

Vehicle A308-5VA Vehicle 626, Vehicle 131, Vehicle 132 and Vehicle 473 are organic vehicles which are resin solutions of various grades of Ethyl cellulose or acrylic resins in a solvent and are available from Ferro Corporation. Via fill material compositions A, B, C and D were then printed through stencils to fill the vias in the silicon wafers. After application of the via fill material, the compositions were dried for 30 seconds at 250° C. or 5-7 minutes at 140 to 180° C. and then fired at 680 to 820° C. for 1-2 seconds at peak in an infrared heated furnace. FIG. 2 is a photomicrograph showing a cross-sectional view of a soldered plug (i.e., a via filled with via fill material) wherein the via fill material is Composition A. FIGS. 3 and 4 are photomicrographs showing cross-sectional views of soldered plugs (i.e., a via filled with via fill material) wherein the via fill material is Composition C.

The series resistance (Rₛ) and shunt resistance (Rₛₕ) were measured using a Solar Cell I-V Tester. The data for formulation D is reported in Table 4 below:

TABLE 4

| | D | |
|---|---|---|
| Series Resistance (Rₛ) | 0.00034 | Ohms |
| Shunt Resistance (Rₛₕ) | 51 | Kohms |

Additional advantages and modifications will readily occur to those skilled in the art. Therefore, the invention in its broader aspects is not limited to the specific details and illustrative examples shown and described herein. Accordingly, various modifications may be made without departing from the spirit or scope of the general inventive concept as defined by the appended claims and their equivalents.

1. A conductive paste comprising:
a. 65-90 wt % silver powder;
b. 0.1-10 wt % of at least one glass frit;
c. a separate and distinct portion of at least one oxide or clay of a metal selected from the group consisting of zirconium, bismuth, aluminum, and combinations thereof; and
d. a separate and distinct portion of at least one oxide or clay of a metal selected from the group consisting of barium, calcium, magnesium silicon, and combinations thereof.

2. The paste of claim 1, wherein the silver powder has at least a bimodal particle size distribution with a first D₅₀ average particle size and a second D₅₀ average particle size.

3. The paste of claim 1, wherein the silver powder has at least a trimodal particle size distribution with a first portion of silver having a first D₅₀ average particle size, a second portion of silver having a second D₅₀ average particle size and a third portion of silver having a third D₅₀ average particle size.

4. The paste of claim 3, wherein the first D₅₀ size is 0.5-5 microns, the second D₅₀ size is 0.5-2.5 microns and the third D₅₀ particle size is 0.1-1.5 microns, wherein the D₅₀ sizes differ by at least 0.1 microns from one another.

5-7. (canceled)

8. The paste of claim 4, wherein the silver powder comprises 20-50 wt % of the first portion, 30-50 wt % of the second portion and 0.1-10 wt % of the third portion.

9-10. (canceled)

11. The paste of claim 3, wherein the first D₅₀ size is 2-20 microns, the second D₅₀ size is 0.5-2.5 microns and the third D₅₀ particle size 0.1-1.5 microns, wherein the D₅₀ sizes differ by at least 0.1 microns from one another.

12-14. (canceled)

15. The paste of claim 11, wherein the silver powder comprises 40-70 wt % of the first portion, 5-25 wt % of the second portion and 1-20 wt % of the third portion.

16-17. (canceled)

18. The paste of claim 3, wherein the silver powder has a first D₅₀ average particle size of 3-15 microns, a second D₅₀ particle size of 0.7-1.5 microns and a third D₅₀ average particle size of 1-3 microns.

19. The paste of claim 1, wherein the sum of (c) and (d) constitutes 0.01-10 wt % of the paste.

20. The paste of claim 1, wherein the clay or oxide of (c) constitutes 0.1 to 5 wt % of the paste.

21. (canceled)

22. The paste of claim 1, wherein the clay or oxide of (c) is a simple oxide of a metal selected from the group consisting of zirconium, bismuth, aluminum and combination thereof.

23. The paste of claim 1, wherein the clay or oxide (d) is a clay of a metal selected from the group consisting of barium, calcium, magnesium, silicon and combinations thereof.

24. The paste of claim 1, wherein the clay or oxide of (c) includes zirconia.

25. The paste of claim 24, wherein the clay or oxide of (c) further comprises alumina.

26. The paste of claim 24, wherein the clay or oxide of (c) includes Bi₂O₃.

27. The paste of claim 24, wherein the clay or oxide of (c) further comprises bentonite.

28. The paste of claim 27, wherein the clay or oxide of (d) includes hectorite.

29. The paste of claim 11, wherein the clay or oxide of (c) includes Bi₂O₃.

30. The paste of claim 1, wherein the paste comprises 74-87 wt % silver powder.

31. The paste of claim 1, wherein the at least one glass frit comprises at least one oxide selected from the group consisting of PbO, P₂O₅, V₂O₅, ZrO₂, SiO₂, Al₂O₃, ZnO and Ta₂O₅.

32. The paste of claim 1, wherein the at least one glass frit comprises PbO, P₂O₅ and V₂O₅.

33. (canceled)

34. The paste of claim 1, wherein the at least one glass frit comprises PbO, ZnO, SiO₂, Al₂O₃ and Ta₂O₅.

35-38. (canceled)

39. An electronic device having substrate comprising a first major surface and a second major surface, and a via having a sidewall extending from the first major surface to the second major surface, the via being filled with a fired conductor material that is capable of conducting electrical current between the first major surface and the second major surface, said conductor material being electrically insulated from the sidewall of the via by an insulation layer that was formed during the firing of the conductor material.

40. A method of producing an electrical device comprising the steps of:
a. providing a substrate having a first surface and an opposed second surface and a via extending between said first surface and said second surface, said via having a sidewall formed along said substrate;
b. applying a conductive filler material into said via, and
c. firing said substrate such that said conductive filler material forms an electrically insulating layer between the conductive filler material and the sidewall and an electrically conductive path extending from the first surface to the second surface.

41. The method of claim 40, wherein the conductive filler does not react with the sidewall during firing.

42-43. (canceled)
